(19) United States
(12) Patent Application Publication
(10) Pub. No.: US 2020/0312911 A1
(43) Pub. Date: Oct. 1, 2020

(54) REDUCING CELL-TO-CELL SWITCH VARIATION IN CROSSBAR ARRAY CIRCUITS

(71) Applicant: TETRAMEM INC., Newark, CA (US)

(72) Inventors: Ning Ge, Newark, CA (US); Minxian Zhang, Newark, CA (US)

(73) Assignee: TETRAMEM INC., Newark, CA (US)

(21) Appl. No.: 16/366,996

(22) Filed: Mar. 27, 2019

(51) Int. Cl. H01L 27/24; H01L 45/00

(52) U.S. Cl. CPC H01L 27/2481; H01L 27/2436; H01L 45/1206; H01L 45/1286; H01L 45/146; H01L 45/1658; H01L 45/1675; H01L 45/1253

(57) ABSTRACT

Technologies relating to one-selector-one-memristor (1S1R) crossbar array circuits methods for reducing 1S1R cell-to-cell switch variations are disclosed. An example apparatus includes: a bottom electrode; a filament forming layer formed on the bottom electrode; an oxidized filament forming layer; a channel forming layer formed on the filament forming layer; an oxidized filament forming layer; a top electrode formed on the channel forming layer, wherein the filament forming layer is configured to form a filament within the filament forming layer, the channel forming layer is configured to form a channel within the channel forming layer when applying a switching voltage upon the filament forming layer and the channel forming layer, and wherein the filament forming layer is surrounded by the oxidized filament forming layer and the channel forming layer is surrounded by the oxidized channel forming layer.

### TECHNICAL FIELD

The present disclosure relates generally to crossbar array circuits with an Insulator-Metal Transition (also referred to as IMT) and a Resistive Random-Access Memory (also referred to as RRAM) and more specifically to a one-selector-one-memristor (also referred to as 1S1R) crossbar array circuit and method of reducing 1S1R cell-to-cell switch variation.

### BACKGROUND

Traditionally, a crossbar array circuit may include horizontal metal wire rows and vertical metal wire columns (or other electrodes) intersecting with each other, with crossbar devices formed at the intersecting points. A crossbar array may be used in non-volatile solid-state memory, signal processing, control systems, high-speed image processing systems, neural network systems, and so on.

A RRAM is a two-terminal passive device capable of changing resistance responsive to sufficient electrical stimulations, which have attracted significant attention for high-performance non-volatile memory applications. The resistance of a RRAM may be electrically switched between two states: a High-Resistance State (HRS) and a Low-Resistance State (LRS). The switching event from a HRS to a LRS is often referred to as a “Set” or “On” switch; the switching systems from a LRS to a HRS is often referred to as a “Reset” or “Off” switching process.

In an RRAM crossbar array circuit, a selector may be required for voltage delivery to a selected RRAM device, to reduce sneak path current, to improve read and write operation, and to reduce power consumption. Transistor has been used as the selector to form a one transistor and one memristor (1T1R) structure. Because a transistor is a three-terminal device, a higher reset current may be needed; also, because a transistor has greater silicon area, manufacturing cost may be higher.

### SUMMARY

Technologies relating to one-selector-one-memristor (1S1R) crossbar array circuits methods for reducing 1 S1R cell-to-cell switch variations are disclosed.

In some implementations, an apparatus includes: a bottom electrode; a filament forming layer formed on the bottom electrode; an oxidized filament forming layer; a channel forming layer formed on the filament forming layer; an oxidized filament forming layer; a top electrode formed on the channel forming layer, wherein the filament forming layer is configured to form a filament within the filament forming layer, the channel forming layer is configured to form a channel within the channel forming layer when applying a switching voltage upon the filament forming layer and the channel forming layer, and wherein the filament forming layer is surrounded by the oxidized filament forming layer and the channel forming layer is surrounded by the oxidized channel forming layer.

In some implementations, the oxidized filament forming layer is less likely than the filament forming layer to form filaments, and the oxidized channel forming layer is less likely than the channel forming layer to form filaments.

In some implementations, a first oxygen concentration of the oxidized channel forming layer is higher than that of the channel forming layer, and a second oxygen concentration of the oxidized filament forming layer is higher than that of the filament forming layer.

In some implementations, a material of the filament forming layer includes TaOₓ (where x≤2.5), HfOₓ (where x≤2), TiOₓ (where x≤2), ZrOₓ (where x≤2), or the combination thereof.

In some implementations, a material of the channel forming layer includes Nb₂O₅, V₂O₅, Ti₂O₃, Ti₂O₅, TiO₂, LaCoO₃, SmNiO₃, or the combination thereof.

In some implementations, a material of the bottom electrode or the top electrode includes Pd, Pt, Ir, W, Ta, Hf, Nb, V, Ti, TiN, TaN, NbN, or the combination of alloy or other conductive materials thereof.

In some implementations, a material of the channel includes VO₂, NbO₂, V₂O₅/VO₂, Nb₂O₅/NbO₂, or the combination thereof.

In some implementations, a material of the filament includes an oxygen vacancy rich material.

In some implementations, the channel forming layer is configured to form the channel within the channel forming layer when a Joule heating is applied from the filament forming layer.

In some implementations, the apparatus further includes: a column wire connected to the bottom electrode; and a row wire connected to the top electrode.

In some implementations, the filament forming layer, the oxidized filament forming layer, the channel forming layer, and the oxidized filament forming layer form a stack, and a shape of the stack is a cylinder.

In some implementations, a first thickness of the oxidized filament forming layer is smaller than a second thickness of the oxidized channel forming layer.

In some implementations, a method includes: forming a bottom electrode on a substrate; forming a filament forming layer on the bottom electrode; forming a channel forming layer on the filament forming layer; forming a top electrode on the channel forming layer; etching and patterning the filament forming layer and the channel forming layer by using the top electrode as a self aligned etch mask; and oxidizing the filament forming layer and the channel forming layer through a first side wall of the filament forming layer and a second side wall of the channel forming layer.

In some implementations, the method further includes: forming a passivation layer covering the oxidizing filament forming layer and the oxidized channel forming layer.

In some implementations, the method further includes: forming a top wire on the top electrode; and forming a bottom wire on the substrate before forming a bottom electrode on the substrate.

### BRIEF DESCRIPTION OF THE DRAWINGS

FIG. 1A is a block diagrams illustrating an example crossbar array circuit in accordance with some implementations of the present disclosure.

FIG. 1B is a block diagrams illustrating an example cross-point device in accordance with some implementations of the present disclosure.

FIG. 2A is a block diagram illustrating an example 1S1R stack with a filament in accordance with the implementations of the present disclosure.

FIG. 2B is a block diagram illustrating an example 1S1R stack with a filament and a channel formed upon a switching current/voltage in accordance with the implementations of the present disclosure.

FIG. 3 is a block diagram illustrating a perspective view of a 1S1R stack in accordance with the implementations of the present disclosure.

FIGS. 4A-4G are block diagrams illustrating various example stages of fabricating a crossbar array circuit in accordance with some implementations of the present disclosure.

FIG. 5 is a block diagram illustrating a top view of an example crossbar array circuit in accordance with some implementations of the present disclosure.

FIG. 6 is a flowchart illustrating an example process for fabricating a crossbar array circuit in accordance with some implementations of the present disclosure.

The implementations disclosed herein are illustrated by way of example, and not by way of limitation, in the figures of the accompanying drawings. Like reference numerals refer to corresponding parts throughout the drawings.

### DETAILED DESCRIPTION

The technology of a 1S1R crossbar array circuit and method of reducing 1S1R cell-to-cell switch variation are disclosed. The technologies described in the present disclosure may provide the following technical advantages.

First, the disclosed technology provides a distinct design of a self-formed channel, volatile, high non-linearity and threshold switching IMT to be a selector and a non-volatile RRAM to be a memristor which forms a one selector one memristor (1S1R) structure of the crossbar array circuit. The self-formed channels and self-aligned to filaments design of the IMT may provide a higher current density and a higher non-linearity which is highly desirable

Second, the design of an oxidation process and oxidized layers, as described in the present disclosure, may reduce conductive path variation, reduce the ion drift and thermal variation during set, reset, and computing operation.

Third, by introducing the process and the structural design of the present disclosure, the process of the fabrication may be simplified and thus the cost is reduced.

Finally, the disclosed technology may also provide technical advantages in applications such as smart wearable electronics, neural networks, signal processing, image recognition, etc. these applications require high accuracy and are vulnerable to random variation from cell-to-cell. Therefore, systems and methods of a 1S1R crossbar array circuit and method of reducing 1S1R cell-to-cell switch variation are therefore desired.

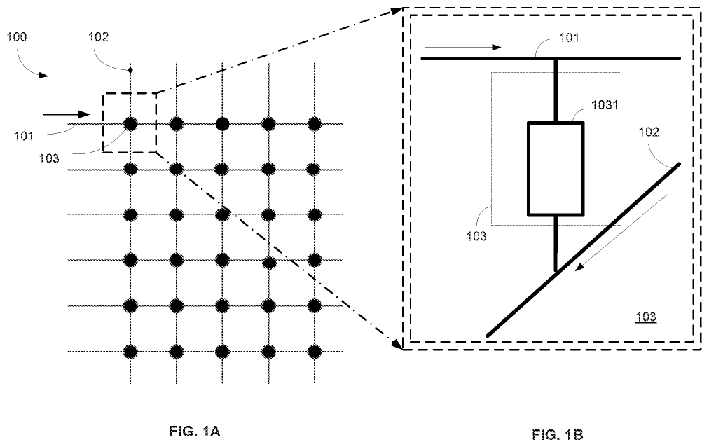

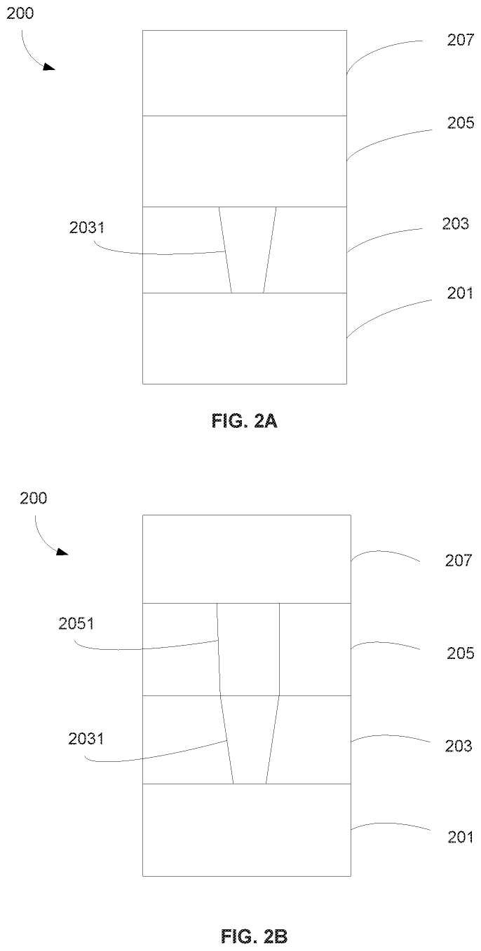

FIG. 1A is a block diagram illustrating an example crossbar array circuit 100 in accordance with some implementations of the present disclosure. As shown in FIG. 1A, the crossbar array circuit 100 includes a first row wire 101, a first column wire 102, and a cross-point device 103.

FIG. 1B is a block diagram illustrating a partially enlarged view of the example cross-point device 103 in accordance with some implementations. As shown FIG. 1B, the cross-point device 103 connects the first row wire 101 and the first column wire 102 of the crossbar array circuit 100. The cross-point device 103 includes a 1S1R stack 1031.

As discussed, a conventional selector may be a transistor which is a three-terminal device having greater silicon area and may thus require to provide a higher reset current to memristor and a higher manufacturing cost. Other selectors may be serially connected with the memristor by an additional floating electrode between a selector and the memristor. In the present implementations, a simplified layer stack of 1S1R includes a special selector and a matching memristor.

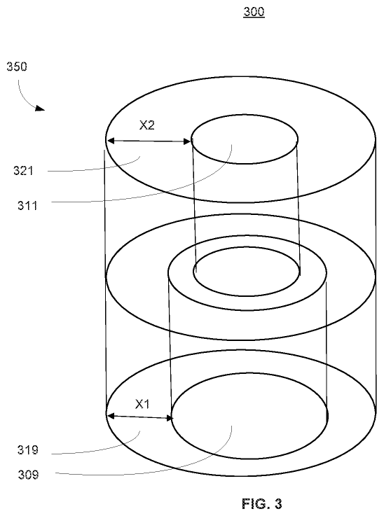

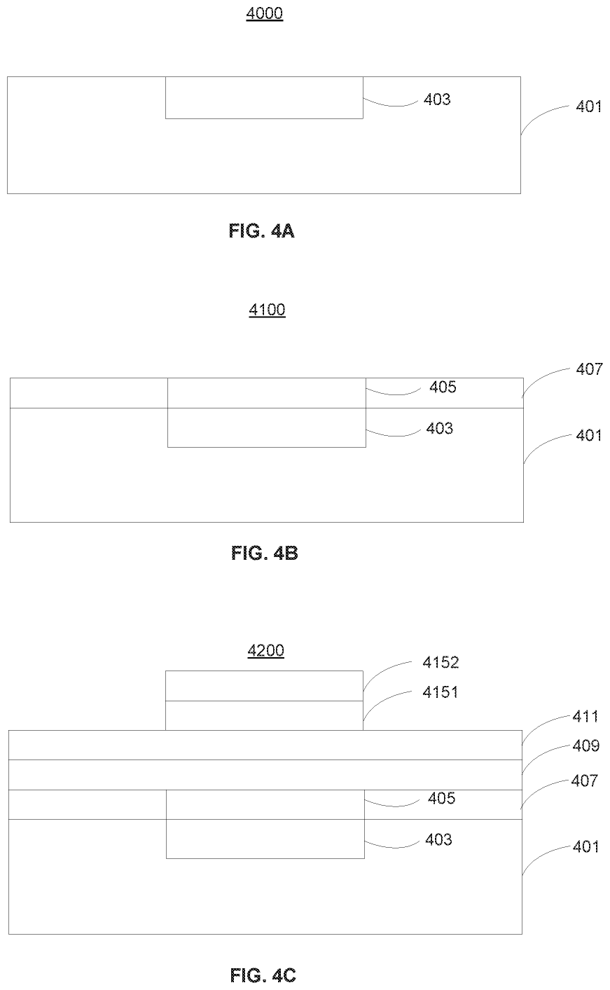

FIG. 2A is a block diagram illustrating a 1S1R stack 200 with a filament 2031 formed upon an initial current/voltage in accordance with the implementations of the present disclosure. As shown in FIG. 2A, the 1S1R stack 200 includes a bottom electrode 201, a filament forming layer 203 formed on the bottom electrode 201, a channel forming layer 205 formed on the filament forming layer 203, and a top electrode 207 formed on the channel forming layer 205.

In some implementations, there are several additional layers inserted between the bottom electrode 201 and the top electrode 207. In some implementations, to provide the self-forming and self-aligned features, the filament forming layer 203 is within a predefined proximity to the channel forming layer 205, so as to provide joule heat to the channel forming layer 205. In some implementations, the positions of the layer 203 and the layer 205 are interchangable.

In some implementations, the filament forming layer 203 is made from one of the following materials: TaOx (where x≤2.5), HfOx (where x≤2.0), TiOx (where x≤2.0), or a combination thereof. In some implementations, the channel forming layer 205 is made from one of the following materials: Nb2O5, NbO2, V2O5, VO2, Ti2O3, Ti2O5, TiO2, LaCoO3, SmNiO3, or a combination thereof. In some implementations, the channel forming layer 205 includes an Insulator-Metal Transition, a Mott transition, or a Negative Differential Resistance (NDR).

In some implementations, the bottom electrode 201 is made from one of the following materials: Pd, Pt, Ir, W, Ta, Hf, Nb, V, Ti, TiN, TaN, NbN, a combination thereof, or an alloy thereof. In some implementations, the top electrode 207 is made from one of the following materials: Pd, Pt, Ir, W, Ta, Hf, Nb, V, Ti, TiN, TaN, NbN, a combination thereof, or an alloy thereof.

When an initial current/voltage is applied to the 1S1R stack 200, the filament 2031 is formed within the filament forming layer 203, which may be seen as a filament in an RRAM. During this forming process, an oxygen vacancy rich filament (e.g., Ta-rich or Hf-rich) 2031 is formed in the filament forming layer 203. Since a filament in an RRAM concentrates all current to a local area at the RRAM/selector interface (which is the interface of the filament forming layer 203 and the channel forming layer 205), the channel forming layer 205 begins to be heated in that local area.

FIG. 2B shows a block diagram illustrating the 1S1R stack 200 with the filament 2031 and a channel 2051 formed responsive to a switching current or voltage in accordance with the implementations of the present disclosure.

When a switching current/voltage is applied to the 1S1R stack 200, a filament 2031 is formed within the filament forming layer 203 and a channel 2051 is formed within the channel forming layer 205. At least two factors may cause the channel 2051 to form above the filament 2031. The first factor is the Joule heating generated from the filament 2031, which improves the oxygen diffusion exponentially in the volume marked by channel 2051. The second factor is the oxygen vacancy rich composition within the filament 2031, which drives oxygen to diffuse from volume market by channel 2051 to filament 2031. The volume market by channel 2051 therefore becomes oxygen poor compared to the rest areas of the channel forming layer 205. This may causes most current to pass through the channel 2051 and little or no leakage current to pass through the rest of the channel forming layer 205. For instance, a NbO₂ channel 2051 is formed within the Nb₂O₅ channel forming layer 205. Since Nb₂O₅ is dielectric which has low leakage current, all the switching current may flow through NbO₂ channel. Therefore, an electrical path is formed by the NbO₂ channel 2051 and the Ta-rich filament 2031. The electrical path may also be referred to as self-formed micro channels within an IMT (channel forming layer) and the self-aligned channels to a filament of a RRAM (filament forming layer).

Since the self-formed NbO₂ micro channel is surrounded by Nb₂O₅ dielectric matrix, all current may pass the micro channel with a high current density, the intense joule heat can effectively cause insulator-metal transition and may provide a higher non-linearity from the insulator-metal transition.

It is noted that when local volume Nb₂O₅ become local NbO₂, the oxygen diffuses to the filament 2031 as:

Nb₂O₅=2NbO₂+O (in TaOx filament)

In some implementations, a material of the channel 2051 is made of a material selected from the one of: VO₂, NbO₂, V₂O₅/VO₂, Nb₂O₅/NbO₂, or a combination thereof. In some implementations, a material of the filament 2031 is made of an oxygen vacancy rich material.

Next, when the current is shut down or turned off, the heat dissipates; the metallic NbO₂ transforms back to the insulative NbO₂; the transformation is a volatile switching. Combined all the processes and physical mechanism, local Joule heating from the filaments through micro channels of NbO₂ makes the channel forming layer 205 (the IMT) to have non-linear I-V, threshold switching, and volatile switching features.

Meanwhile, when the current is shut down or turned off, the filament state of RRAM remains unchanged, despite the removal of the current; the RRAM may thus remain in its current resistance state. Therefore, the RRAM remains a non-volatile switching, and so does the entire 1S1R stack. It is noted that, in some implementations, the RRAM filament state may be changed, responsive to a high current/voltage being applied to set or reset the RRAM. In some implementations, the 1S1R stack 200 may be the same as the 1S1R stack 1031.

The conductive path through 1S1R cell may be form at a random location within a cell: near the center of the cell, near the edge of the cell, or between the center and the edge of the cell. This uncertainty or randomness of a conductive path's location and shape may cause switching variations from cell to cell in a 1S1R crossbar array circuit. The technologies, e.g., fabrication processes and 1S1R structures, described in the present disclosure can reduce these switching variations.

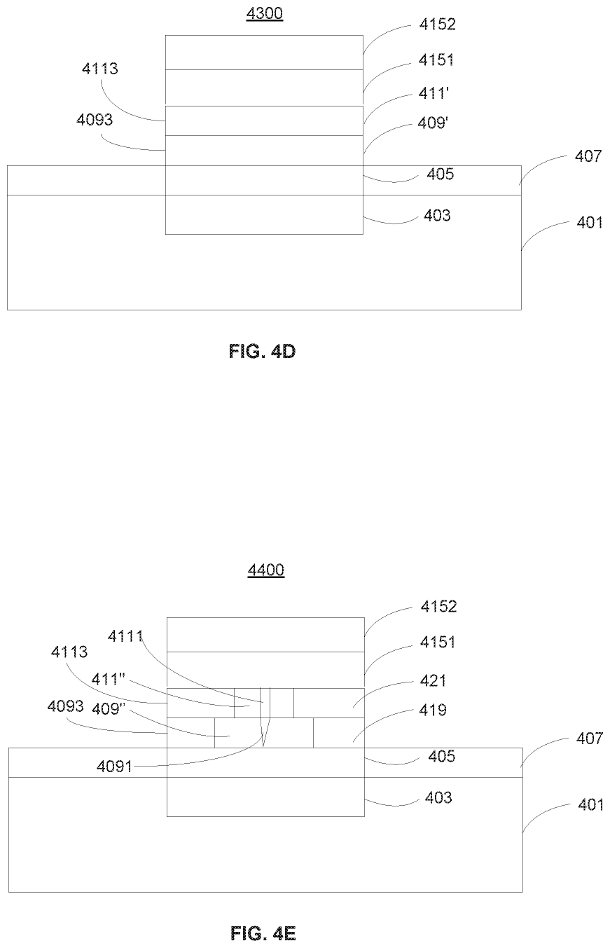

FIG. 3 is a block diagram illustrating an example 1S1R stack in accordance with the implementations of the present disclosure.

One technical solution to reducing switching variations includes: centering the 1S1R conductive path filament within each 1S1R cell. This may reduce conductive path variations, as well as ion drift and thermal variations, during set and reset operations.

As shown in FIG. 3, the 1S1R stack 350 includes an oxidized filament forming layer 319, and a filament forming layer 309 formed in the oxidized filament forming layer 319. The partial 1S1R stack 350 also includes an oxidized channel forming layer 321 and a channel forming layer 311 formed in the oxidized channel forming layer 321. The oxidized channel forming layer 321 and the channel forming layer 311 are formed on the oxidized filament forming layer 319 and the filament forming layer 309. In some implementations, a shape of the partial 1S1R stack 350 may be a cylinder shape, a triangle prism, or a rectangular prism.

Using an example Ta₂O₅/Nb₂O₅ 1S1R stack as an example:

First, for the process temperature versus growing speed check:

Since the diffusion formula: D=Dₒ exp(−Q/RT), where D is the diffusion coefficient or diffucivity at temperature T, Do is a constant, Q is the activation energy, R is the gas constant, and T is the temperature is Kelvin.

1. For Oxygen diffusion in Ta₂O₅

Dₒ=8.6E(−11) m²/s

Q=1.2 eV

Therefore, at 400° C. (673K), D_{Ta205}=9.8E(−20) m²/s=9.8E(−2) nm²/s.

2. For Oxygen diffusion in Nb₂O₅

Dₒ=9.4E(−12) m²/s

Q=1.0 eV

At 400° C. (673K), D_{Nb2O5}=3.3E(−19) m²/s=3.3E(−1) nm²/s

The diffusivity ratio of two layers:

At 400° C., D_{Nb2O5}/D_{Ta2O5}=0.33/0.098=3.4, and (D_{Nb2O5}/D_{Ta2O5})^{1/2}=1.8

For one-dimensional diffusion, the relation between diffusion distance X, diffusion coefficient D, and diffusion time t is

X²=2Dt, or X=(2Dt)^{1/2}

Therefore, at same temperature (400° C.) and same time, X_{Nb2O5}/X_{Ta2O5}=(D_{Nb2O5}/D_{Ta2O5})^{1/2}=1.8

At 400° C., assume X_{Nb2O5}=10 nm, then X_{Ta2O5}=5.6 nm

Consequently, this estimation suggests that a 10 nm Nb₂O₅ sidewall and 5.56 nm Ta₂O₅ sidewall may be formed simultaneously if the cylinder stack is oxidized at 400° C.

Second, we perform a sanity check on oxidation time:

1. To growth 10 nm Nb₂O₅ at 400° C.,

t_{Nb2O5}=(X_{Nb2O5})²/(2D^{Nb2O5})=(10 nm)²/(2*0.33 nm²/s)=152 s

2. To growth 5.6 nm Ta₂O₅ at 400° C.,

t_{Ta2O5}=(X_{Ta2O5})²/(2D_{Ta2O5})=(5.56 nm)²/(2*0.098 nm²/s)=158 s

Therefore, the calculated t_{Nb2O5} and t_{Ta2O5} are approximately the same.

Based on the estimation, for a 30 nm diameter cylinder cell stack:

Nb₂O₅ sidewall−10 nm, with a 10 nm diameter NbO₂ core.

(Core area/cell area)=10\hat{ }2/30\hat{ }2=0.11 (89% reduction in selector conductive area).

Ta₂Oₛ sidewall ˜5.56 nm, with an 18.9 nm TaOₓ core.

(Core area/cell area)=18.9\hat{ }2/30\hat{ }2=0.40 (60% reduction in RRAM area available to grow a filament).

The estimations above demonstrate some of the technical advantages provided by the technologies disclosed in the present disclosure: cell to cell switching variation may be reduced by reducing the area available to form filament or channel, for example, by 60-90%.

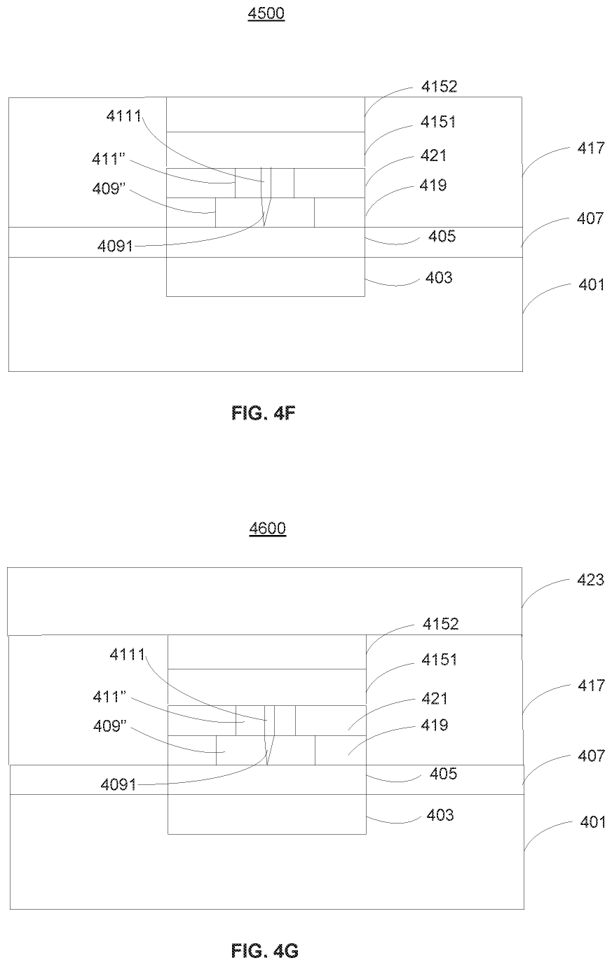

FIGS. 4A-4G are block diagrams illustrating various example stages of fabricating a crossbar array circuit in accordance with some implementations of the present disclosure.

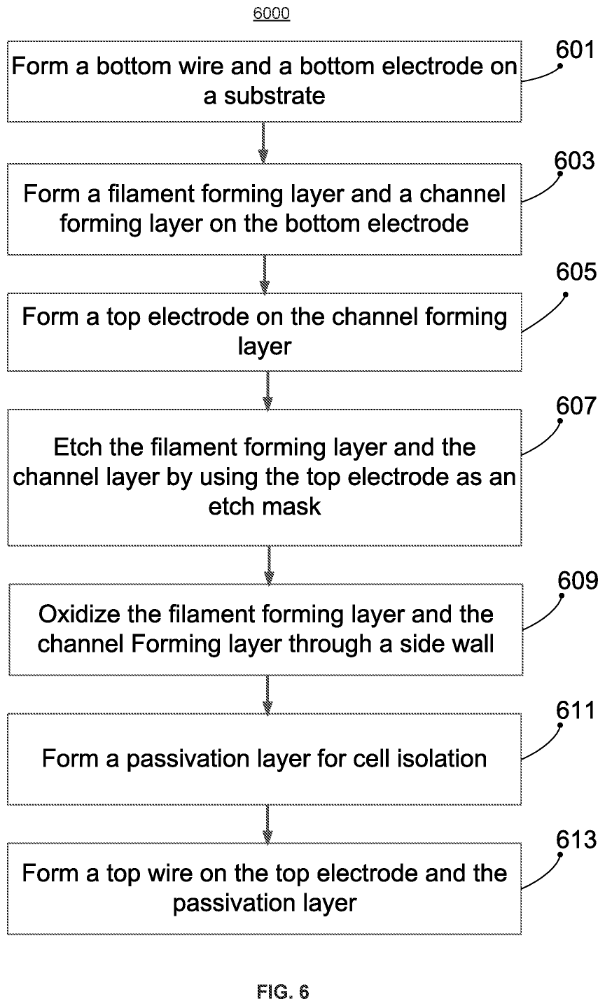

As shown in FIGS. 4A-4B, a substrate 401 is provided, and a bottom wire 403 and a bottom electrode 405 are formed on the substrate 401. This may correspond to the step 601 shown in FIG. 6.

As shown in FIG. 4A, in some implementations, the substrate 401 is patterned and etched with a ditch and the bottom wire 403 is deposited on the substrate and the ditch. A Chemical Mechanical Polishing/Planarization (CMP) process may then be used to form the bottom wire 403. In some implementations, the bottom wire 403 may be made of one of: Al, Au, Cu, Fe, Ni, Mo, Pt, Pd, Ti, TiN, Sn, W, Zn, a combination thereof or an alloy thereof (with or without other conductive materials). A diffusion barrier material such as TiN, TaN and so on may also be applied to prevent reaction between bottom wire material and the substrate material. In some implementations, the bottom wire 403 is a column wire.

As shown in FIG. 4B, in some implementations, the bottom electrode 405 is fabricated on the bottom wire 403. An interlayer 407 may be deposited on the substrate 401 and the bottom wire 403. Then, the interlayer 406 is patterned and etched to the bottom wire 403; the bottom electrode 405 is deposited on the bottom wire 403 and the interlayer 407; and a Chemical Mechanical Polishing/Planarization (CMP) process may then be used for surface planarization purpose. The bottom electrode 405 may be made of one of: Pt, Ti, TiN, Pd, Ir, W, Ta, Hf, Nb, V, TaN, NbN, a combination thereof, or an alloy thereof (with or without other conductive materials). In some implementations, the bottom electrode 405 is used to provide a better ohmic contact. In some implementations, the interlayer 407 may be made of one of: Al2O3, SiO2, SiN, AlN, MgO, TiO2, AlOxNy, SiOxNy, or a combination thereof.

As shown in FIG. 4C, in some implementations, a filament forming layer 409 is formed on the bottom electrode 405 and the interlayer 407, and a channel forming layer 411 is formed on the filament forming layer 409. This may correspond to the step 603 shown in FIG. 6.

In some implementations, the filament forming layer 409 is made of one of: TaOx (where x≤2.5), HfOx (where x≤2.0), TiOx (where x≤2.0), ZrOx (where x≤2.0) or a combination thereof. In some implementations, a material of the channel forming layer 411 is made of one of: NbO2, VO2, Ti2O3, TiO2, LaCoO3, SmNiO3 or a combination thereof.

A first top electrode 4151 and a second top electrode 4152 may then be formed on the channel forming layer 411. This may correspond to the step 605 shown in FIG. 6.

In some implementations, the process of forming the first top electrode 4151 and the second top electrode 4152 may include: spin coating a photoresist on the channel forming layer 411, opening via in the photoresist, depositing the first top electrode 4151 and the second top electrode 4152 on the channel forming layer 411 and the photoresist, and then removing the photoresist.

In some implementations, the first top electrode 4151 is made of one of: Pt, Ti, TiN, Pd, Ir, W, Ta, Hf, Nb, V, TaN, NbN, a combination thereof, or an alloy thereof (with or without other conductive materials). In some implementations, the first top electrode 4151 is configured to provide a better ohmic contact.

In some implementations, the second top electrode 4152 is made of one of: Pt, Ti, TiN, Pd, Ir, W, Ta, Hf, Nb, V, TaN, NbN, a combination thereof, or an alloy thereof (with or without other conductive materials). In some implementations, the second top electrode 4152 is used as a mask to etch the filament forming layer 409 and the channel forming layer 411.

As shown in FIG. 4D, in some implementations, the filament forming layer 409 and the channel forming layer 411 are etched by using the second top electrode 4152 (and the first top electrode 4151) as the etch mask to form the filament forming layer 409′ and the channel forming layer 411′. This may correspond to the step 607 shown in FIG. 6. A first side wall of the filament forming layer 4093 and a second side wall of the channel forming layer 4113 are formed thereafter.

As shown in FIG. 4E, in some implementations, the filament forming layer 409′ and the channel forming layer 411′ are oxidized through the first side wall 4093 and the second side wall 4113 to form an oxidized filament forming layer 419, an oxidized channel forming layer 421, the remaining filament forming layer 409″, and the channel forming layer 411″. This may correspond to the step 609 shown in FIG. 6.

In some implementation, the oxidized filament forming layer 419 is formed on a side wall of the filament forming layer 409″; the oxidized channel forming layer 421 is formed on a side wall of the channel forming layer 411″. The filament forming layer 409″ is surrounded by the oxidized filament forming layer 419; the channel forming layer 411″ is surrounded by the oxidized channel forming layer 421.

Responsive to a switching voltage being applied onto the filament forming layer 409″ and the channel forming layer 411″, the filament forming layer 409″ is configured to form a filament 4091 within the filament forming layer 409″ and the channel forming layer 411″ is configured to form a channel 4111 within the channel forming layer 411″.

To avoid confusion, it is noted that, in some implementations, filament 4091 and channel 4011 are not formed during a 1S1R cell fabrication process; instead, they are formed during initial cell forming and operation. Therefore, with reference to at least FIG. 4E to 4G, the filament 4091 and the channel 4011 are for illustration of the cell in operation.

In some implementations, the oxidized filament forming layer 419 may not be able to form the filament 4091 within the oxidized filament forming layer 419, and the oxidized channel forming layer 421 may not be able to form the channel 4111 within the oxidized channel forming layer 421. In some implementations, the oxidized filament forming layer 419 is less likely than the filament forming layer 409″ to form filaments 4091 when a switching voltage is applied to the oxidized filament forming layer 419. The oxidized channel forming layer 421 is less likely than the channel forming layer 411″ to form filaments 4111 when a switching voltage is applied to the oxidized channel forming layer 421.

The filament 4091 may be made of an oxygen vacancy rich material; and the channel 4111 may be made of one of: VO2, NbO2, V2O5/VO2, Nb2O5/NbO2, or a combination thereof.

Fabricating full oxide side walls for both the filament forming layer 409′ (1R) and the channel forming layer 411′ (1S) under a controlled oxidizing atmosphere (oxidizer, pressure, temperature, time etc.) may result in 1R and 1S having different sidewall thicknesses. When oxygen diffuses fast in one oxide, the corresponding side wall may be thicker, and the core may be smaller. For instance, oxygen diffuses faster in Nb2O5 than in Ta2O5 at 400° C.; as a result, the 1S side wall may be thicker than the 1R side wall. In some implementations, a first thickness of the oxidized filament forming layer 419 is less than a second thickness of the oxidized channel forming layer 421.

In some implementations, the oxidized filament forming layer 419 is made of one of TaOₓ (where x≤2.5), HfOₓ (where x≤2.0), TiOₓ (where x≤2.0), ZrOₓ (where x≤2.0), or a combination thereof; the oxidized channel forming layer 421 is made of one of Nb₂O₅, NbO₂, V₂O₅, VO₂, Ti₂O₃, Ti₂O₅, TiO₂, LaCoO₃, or a combination thereof.

In some implementations, an oxygen concentration of the oxidized channel forming layer 421 is higher than that of the channel forming layer 411″, and an oxygen concentration of the oxidized filament forming layer 419 is higher than that of the filament forming layer 409″.

Because the diffusion of the oxide may not evenly distributed among the oxidized channel forming layer 421 and the oxidized filament forming layer 419, the oxygen concentration in these layers is not a uniformed, but an average value. The boundary between layers may not be observable due to the diffusion phenomenon. Therefore, in some implementations, the oxidized channel forming layer 421 and the channel forming layer 411″ are a single channel forming layer (so are the oxidized filament forming layer 419 and the filament forming layer 409″) which has an inner side and an outer side; the oxygen concentration in the outer side may be higher than that in the inner side.

As shown in FIG. 4F, a passivation layer 417 may be formed for 1S1R cell isolation and a CMP process may be applied for the purpose of surface planarization. This may correspond to the step 611 shown in FIG. 6.

The passivation layer 417 may cover the oxidized filament forming layer and the oxidized channel forming layer. In some implementations, an additional coating layer may be formed on the cell side wall or spacer for better cell isolation, before the deposition occurs on the passivation layer 417. In some implementations, the passivation layer 417 is made of one of: Al2O3, SiO2, SiN, AlN, MgO, TiO2, AlON, or a combination thereof.

As shown in FIG. 4G, a top wire 423 may next be formed on the second top electrode 4152 and the passivation layer 417. This may correspond to the step 613 shown in FIG. 6.

Forming the top wire 423 on the second top electrode 4152 and the passivation layer 417 may include: forming a dielectric interlayer; etching a ditch along the second top electrode 4152; forming the top wire 423 on the second top electrode 4152 and the passivation layer 417; and applying a CMP for the purpose of surface planarization.

In some implementations, a material of the top wire 423 may be made of one of: Al, Au, Cu, Fe, Ni, Mo, Pt, Pd, Sn, W, Zn, Ti, TiN, a combination thereof, or an alloy thereof (with or without other conductive materials). The top wire 423 may be a row wire within the crossbar array circuit 100.

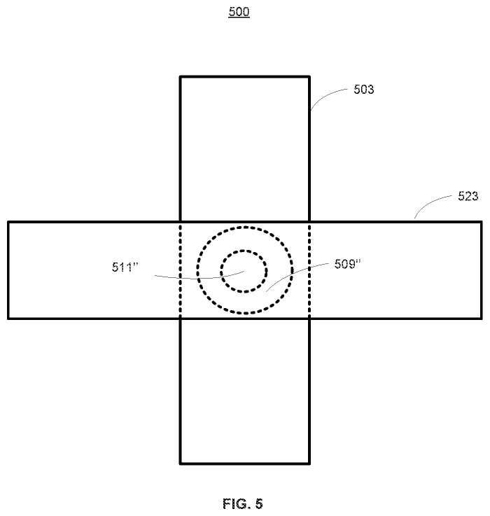

FIG. 5 is a block diagram illustrating a top view of an example crossbar array circuit 500 in accordance with some implementations of the present disclosure.

In a top view, as shown in FIG. 5, the 1S1R cell is of a circular shape. The top wire 523 and the bottom wire 503 are both connected to the 1S1R cell, which includes the filament forming layer 509″ and the channel forming layer 511″ in a column or in a row to form the crossbar array circuit 500. The crossbar array circuit 500 may be the circuit 100 shown in FIG. 1.

FIG. 6 is a flowchart illustrating an example process 600 for fabricating a crossbar array circuit in accordance with some implementations of the present disclosure. Example steps included in the process 600 are discussed with reference to at least FIGS. 4A-4G.

Plural instances may be provided for components, operations or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the implementation(s). In general, structures and functionality presented as separate components in the example configurations may be implemented as a combined structure or component. Similarly, structures and functionality presented as a single component may be implemented as separate components. These and other variations, modifications, additions, and improvements fall within the scope of the implementation(s).

It will also be understood that, although the terms “first,” “second,” etc. may be used herein to describe various elements, these elements should not be limited by these terms. These terms are only used to distinguish one element from another. For example, a first column could be termed a second column, and, similarly, a second column could be termed the first column, without changing the meaning of the description, so long as all occurrences of the “first column” are renamed consistently and all occurrences of the “second column” are renamed consistently. The first column and the second are columns both column s, but they are not the same column.

The terminology used herein is for the purpose of describing particular implementations only and is not intended to be limiting of the claims. As used in the description of the implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined (that a stated condition precedent is true)” or “if (a stated condition precedent is true)” or “when (a stated condition precedent is true)” may be construed to mean “upon determining” or “in response to determining” or “in accordance with a determination” or “upon detecting” or “in response to detecting” that the stated condition precedent is true, depending on the context.

The foregoing description included example systems, methods, techniques, instruction sequences, and computing machine program products that embody illustrative implementations. For purposes of explanation, numerous specific details were set forth in order to provide an understanding of various implementations of the inventive subject matter. It will be evident, however, to those skilled in the art that implementations of the inventive subject matter may be practiced without these specific details. In general, well-known instruction instances, protocols, structures, and techniques have not been shown in detail.

The foregoing description, for purpose of explanation, has been described with reference to specific implementations. However, the illustrative discussions above are not intended to be exhaustive or to limit the implementations to the precise forms disclosed. Many modifications and variations are possible in view of the above teachings. The implementations were chosen and described in order to best explain the principles and their practical applications, to thereby enable others skilled in the art to best utilize the implementations and various implementations with various modifications as are suited to the particular use contemplated.

What is claimed is:

1. An apparatus comprising:
a bottom electrode;
a filament forming layer formed on the bottom electrode;
an oxidized filament forming layer;
a channel forming layer formed on the filament forming layer;
an oxidized filament forming layer;
a top electrode formed on the channel forming layer, wherein the filament forming layer is configured to form a filament within the filament forming layer, the channel forming layer is configured to form a channel within the channel forming layer when applying a switching voltage upon the filament forming layer and the channel forming layer, and wherein the filament forming layer is surrounded by the oxidized filament forming layer and the channel forming layer is surrounded by the oxidized channel forming layer.

2. The apparatus as claimed in claim 1, wherein the oxidized filament forming layer is less likely than the filament forming layer to form filaments, and the oxidized channel forming layer is less likely than the channel forming layer to form channels.

3. The apparatus as claimed in claim 1, wherein a first oxygen concentration of the oxidized channel forming layer is higher than that of the channel forming layer, and a second oxygen concentration of the oxidized filament forming layer is higher than that of the filament forming layer.

4. The apparatus as claimed in claim 1, wherein a material of the filament forming layer comprises TaOₓ (where x≤2.5), HfOₓ (where x≤2), TiOₓ (where x≤2), ZrOₓ (where x≤2), or the combination thereof.

5. The apparatus as claimed in claim 1, wherein a material of the channel forming layer comprises Nb₂O₅, V₂O₅, Ti₂O₃, Ti₂O₅, TiO₂, LaCoO₃, SmNiO₃, or a combination thereof.

6. The apparatus as claimed in claim 1, wherein a material of the bottom electrode or the top electrode comprise Pd, Pt, Ir, W, Ta, Hf, Nb, V, Ti, TiN, TaN, NbN, a combination of any of these material, or an alloy of any of these materials with other conductive materials.

7. The apparatus as claimed in claim 1, wherein a material of the channel comprises VO₂, NbO₂, V₂O₅/VO₂, Nb₂O₅/NbO₂, or a combination thereof.

8. The apparatus as claimed in claim 1, wherein a material of the filament comprises an oxygen vacancy rich material.

9. The apparatus as claimed in claim 1, wherein the channel forming layer is configured to form the channel within the channel forming layer when a Joule heating is applied from the filament forming layer.

10. The apparatus as claimed in claim 1, further comprises:
a column wire connected to the bottom electrode; and
a row wire connected to the top electrode.

11. The apparatus as claimed in claim 1, wherein the filament forming layer, the oxidized filament forming layer, the channel forming layer, and the oxidized channel forming layer forms a stack, and a shape of the stack is a cylinder.

12. The apparatus as claimed in claim 1, wherein a first thickness of the oxidized filament forming layer is less than a second thickness of the oxidized channel forming layer.

13. A method comprising:
forming a bottom electrode on a substrate;
forming a filament forming layer on the bottom electrode;
forming a channel forming layer on the filament forming layer;
forming a top electrode on the channel forming layer;
etching the filament forming layer and the channel forming layer by using the top electrode as a self-aligned etch mask; and
oxidizing the filament forming layer and the channel forming layer through a first side wall of the filament forming layer and a second side wall of the channel forming layer.

14. The method as claimed in claim 13, further comprising:
forming a passivation layer covering the oxided filament forming layer and the oxidized channel forming layer.

15. The method as claimed in claim 13, further comprising:
forming a top wire on the top electrode; and
forming a bottom wire on the substrate before forming a bottom electrode on the substrate.
